(19) United States
(12) Patent Application Publication
(10) Pub. No.: US 2018/0061507 A1
(43) Pub. Date: Mar. 1, 2018

(54) FUSE STATE SENSING CIRCUITS, DEVICES AND METHODS

(71) Applicant: SKYWORKS SOLUTIONS, INC., Woburn, MA (US)

(72) Inventors: Yan YAN, Irvine, CA (US); Yunyoung CHOI, Irvine, CA (US); Junhyung LEE, Irvine, CA (US)

(21) Appl. No.: 15/687,764

(22) Filed: Aug. 28, 2017

Related U.S. Application Data
(60) Provisional application No. 62/380,861, filed on Aug. 29, 2016.

(51) Int. Cl. G11C 17/16; H01L 23/525; H01L 27/112

(52) U.S. Cl. CPC G11C 17/16; H01L 27/11206; H01L 23/5256

(57) ABSTRACT

Fuse state sensing circuits, devices and methods. In some embodiments, a fuse state sensing circuit can include an enable block configured to enable a flow of a fuse current resulting from a supply voltage to a fuse element upon receipt of an enable signal substantially at the same time as when the supply voltage is applied. The fuse state sensing circuit can further include a current control block tailored to control an amount of the fuse current. The fuse state sensing circuit can further include a decision block implemented to generate an output representative of a state of the fuse element based on the fuse current, with the output being generated during a ramp-up portion of the application of the supply voltage.

### CROSS-REFERENCE TO RELATED APPLICATION(S)

This application claims priority to U.S. Provisional Application No. 62/380,861 filed Aug. 29, 2016, entitled FUSE STATE SENSING CIRCUITS, DEVICES AND METHODS, the disclosure of which is hereby expressly incorporated by reference herein in its respective entirety.

### BACKGROUND

### Field

The present disclosure relates to fuse state sensing technology implemented in semiconductor devices.

Description of the Related Art

In many integrated circuits implemented on semiconductor devices such as die, fuses can be utilized to store information. For example, fuse-stored values can provide information about part-to-part and/or process variations among different integrated circuit die. With such information, a given integrated circuit die can be operated appropriately to provide desired functionality.

### SUMMARY

In accordance with some implementations, the present disclosure relates to a fuse state sensing circuit that includes an enable block configured to enable a flow of a fuse current resulting from a supply voltage to a fuse element upon receipt of an enable signal substantially at the same time as when the supply voltage is applied. The fuse state sensing circuit further includes a current control block tailored to control an amount of the fuse current, and a decision block implemented to generate an output representative of a state of the fuse element based on the fuse current, with the output being generated during a ramp-up portion of the application of the supply voltage.

In some embodiments, the enable block can be further configured to enable a flow of a reference current resulting from the supply voltage to a reference element upon receipt of the enable signal. The current control block can be further tailored to control an amount of the reference current. The decision block can be further implemented to generate the output based on the fuse current and the reference current. The decision block can include a supply node for receiving the supply voltage, such that the decision block receives the supply voltage. The enable block can include a fuse node for connecting to the fuse element, such that the current control block is implemented between the decision block and the enable block.

In some embodiments, the decision block, the enable block, and the current control block can be interconnected by a fuse current path between a supply node configured to receive the supply voltage and a fuse node configured to be connected to the fuse element. The decision block, the enable block, and the current control block can be further interconnected by a reference current path between the supply node and a reference node configured to be connected to a reference element.

In some embodiments, the reference element can include a reference resistance. One end of the fuse element can be connected to the fuse node and the other end of the fuse element can be connected to a ground. One end of the reference element can be connected to the reference node and the other end of the reference element can be connected to the ground. The fuse current path and the reference current path can be electrically parallel between the supply node and the ground.

In some embodiments, the fuse current path can include a decision transistor, a current control transistor, and an enable transistor implemented in series between the supply node and the fuse node. The decision transistor can be connected to the supply node and the enable transistor can be connected to the fuse node, such that the current control transistor is between the decision transistor and the enable transistor. The reference current path can include a decision transistor, a current control transistor, and an enable transistor implemented in series between the supply node and the reference node. The decision transistor can be connected to the supply node and the enable transistor can be connected to the reference node, such that the current control transistor is between the decision transistor and the enable transistor.

In some embodiments, the enable transistor of the fuse current path and the enable transistor of the reference current path can be parts of the enable block. Each of the enable transistor of the fuse current path and the enable transistor of the reference current path can include a gate, a source, and a drain to allow flow of a current between the drain and the source upon application of a gate voltage. Each enable transistor can be, for example, an n-type field-effect transistor. The source of the enable transistor of the reference current path can be connected to the reference node, and the source of the enable transistor of the fuse current path can be connected to the fuse node. The gate of each enable transistor can be connected to an enable node for receiving the enable signal as the gate voltage.

In some embodiments, the current control transistor of the fuse current path and the current control transistor of the reference current path can be parts of the current control block. Each of the current control transistor of the fuse current path and the current control transistor of the reference current path can include a gate, a source, and a drain to allow flow of a current between the drain and the source upon application of a gate voltage. Each current control transistor can be, for example, an n-type field-effect transistor.

In some embodiments, the drain of the current control transistor of the reference current path can be connected to a drain of the decision transistor of the reference current path, and the drain of the current control transistor of the fuse current path can be connected to a drain of the decision transistor of the fuse current path. The gate of each current control transistor can be connected to the supply node such that the gate receives the supply voltage as the gate voltage.

In some embodiments, the decision transistor of the fuse current path and the decision transistor of the reference current path can be parts of the decision block. The decision block can further include a first output node along the reference current path, and a second output node along the fuse current path, with the first and second output nodes being configured to provide respective output voltages based on the state of the fuse element. Each of the decision transistor of the fuse current path and the decision transistor of the reference current path can include a gate, a source, and a drain, such that the source of each decision transistor is connected to the supply node and the drain of each decision transistor is connected to a respective one of the first and second output nodes. Each decision transistor can be, for example, a p-type field-effect transistor.

In some embodiments, the decision transistor of the reference current path and the decision transistor of the fuse current path can be cross-coupled, such that the gate of one decision transistor is connected to the drain of the other decision transistor. The output of the decision block can include a difference between the first output voltage and the second output voltage. The decision block can be configured such that the output has a positive value when the fuse element is in an intact state and a negative value when the fuse element is in a blown state.

In some embodiments, the decision block can further include a switchable coupling path between the supply node and each of the first and second output nodes. The switchable coupling path can be configured to be non-conducting during a fuse sensing operation, and conducting when the sensing operation is completed such that the conducting coupling path allows each of the first and second output nodes to be substantially at the supply voltage. Each switchable coupling path can include a switching transistor electrically parallel with the corresponding decision transistor.

In some embodiments, the decision block can further include a switchable resistive path from each of the first and second output nodes. The switchable resistive path can be configured to be conducting during a fuse sensing operation, and non-conducting when the sensing operation is completed, to provide an additional discharging path. Each switchable resistive path can include a switching transistor in series with an output resistance.

In some embodiments, each current control transistor of the fuse current path and the reference current path can have an active area with a width and a length, such that for a given length the width is tailored to reduce the corresponding current while maintaining a desired margin of reliability for the output of the decision block. In some embodiments, the desired margin of reliability can be at least 1% of a width range between a minimum width of reliability and a selected maximum width, with the at least 1% being from the minimum width. In some embodiments, the desired margin of reliability can be at least 5% of the width range, from the minimum width. In some embodiments, the desired margin of reliability can be at least 10% of the width range, from the minimum width.

In some teachings, the present disclosure relates to a fuse system for an electronic device. The fuse system includes a fuse element formed on a semiconductor die, and a fuse sensing circuit in communication with the fuse element and including an enable block configured to enable a flow of a fuse current resulting from a supply voltage to the fuse element upon receipt of an enable signal substantially at the same time as when the supply voltage is applied. The fuse sensing circuit further includes a current control block tailored to control an amount of the fuse current, and a decision block implemented to generate an output representative of a state of the fuse element based on the fuse current, with the output being generated during a ramp-up portion of the application of the supply voltage. The fuse system further includes an output circuit configured to receive the output from the fuse sensing circuit and generate a logic signal and provide the logic signal to a control circuit.

In some embodiments, the control circuit can include a Mobile Industry Processor Interface controller. In some embodiments, the fuse sensing circuit can be implemented on the semiconductor die.

In some implementations, the present disclosure relates to a semiconductor die that includes a semiconductor substrate, and a fuse element implemented on the semiconductor substrate. The semiconductor die further includes a fuse sensing circuit implemented on the semiconductor substrate and in communication with the fuse element. The fuse sensing circuit includes an enable block configured to enable a flow of a fuse current resulting from a supply voltage to the fuse element upon receipt of an enable signal substantially at the same time as when the supply voltage is applied. The fuse sensing circuit further includes a current control block tailored to control an amount of the fuse current, and a decision block implemented to generate an output representative of a state of the fuse element based on the fuse current, with the output being generated during a ramp-up portion of the application of the supply voltage.

In a number of implementations, the present disclosure relates to an electronic module that includes a packaging substrate configured to receive a plurality of components, and a semiconductor die mounted on the packaging substrate and including an integrated circuit and a fuse element. The electronic module further includes a fuse sensing circuit in communication with the fuse element and including an enable block configured to enable a flow of a fuse current resulting from a supply voltage to the fuse element upon receipt of an enable signal substantially at the same time as when the supply voltage is applied. The fuse sensing circuit further includes a current control block tailored to control an amount of the fuse current, and a decision block implemented to generate an output representative of a state of the fuse element based on the fuse current, with the output being generated during a ramp-up portion of the application of the supply voltage. The electronic module further includes a controller in communication with the fuse sensing circuit and configured to receive an input signal representative of the output of the fuse sensing circuit. The controller is further configured to generate a control signal based on the input signal.

In some embodiments, the integrated circuit can be a radio-frequency integrated circuit. The radio-frequency integrated circuit can be a receiver circuit. The electronic module can be, for example, a diversity receive module. The controller can be configured to provide, for example, a Mobile Industry Processor Interface signal as the control signal.

In some implementations, the present disclosure relates to an electronic device that includes a processor and a semiconductor die having an integrated circuit configured to facilitate operation of the electronic device under a control of the processor. The semiconductor die further includes a fuse element. The electronic device further includes a fuse sensing circuit in communication with the fuse element and including an enable block configured to enable a flow of a fuse current resulting from a supply voltage to the fuse element upon receipt of an enable signal substantially at the same time as when the supply voltage is applied. The fuse sensing circuit further includes a current control block tailored to control an amount of the fuse current, and a decision block implemented to generate an output representative of a state of the fuse element based on the fuse current, with the output being generated during a ramp-up portion of the application of the supply voltage. The electronic device further includes a controller in communication with the fuse sensing circuit and configured to receive an input signal representative of the output of the fuse sensing circuit. The controller is further configured to generate a control signal based on the input signal.

In some embodiments, the electronic device can be a wireless device such as a cellular phone.

In some implementations, the present disclosure relates to a wireless device that includes an antenna configured to at least receive a radio-frequency signal, and a receive module configured receive and process the radio-frequency signal. The receive module has a semiconductor die that includes an integrated circuit and a fuse element, and a fuse sensing circuit in communication with the fuse element and including an enable block configured to enable a flow of a fuse current resulting from a supply voltage to the fuse element upon receipt of an enable signal substantially at the same time as when the supply voltage is applied. The fuse sensing circuit further includes a current control block tailored to control an amount of the fuse current, and a decision block implemented to generate an output representative of a state of the fuse element based on the fuse current, with the output being generated during a ramp-up portion of the application of the supply voltage. The receive module further includes a controller in communication with the fuse sensing circuit and configured to receive an input signal representative of the output of the fuse sensing circuit, and to generate a control signal based on the input signal.

In some embodiments, the antenna can be, for example, a diversity antenna.

According to some teachings, the present disclosure relates to a method for sensing a state of a fuse element. The fuse includes receiving an enable signal and a supply voltage substantially and the same time, and enabling a flow of a fuse current resulting from the supply voltage to a fuse element based on the enable signal. The method further includes controlling an amount of the fuse current, and generating an output representative of a state of the fuse element based on the fuse current, with the output being generated during a ramp-up portion of the application of the supply voltage.

In some embodiments, the method can further include enabling a flow of a reference current resulting from the supply voltage to a reference element upon receipt of the enable signal, and controlling an amount of the reference current. The generating of the output can include generating the output based on the fuse current and the reference current.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a fuse system that includes a fuse sensing circuit having one or more features as described herein.

FIG. 2 shows that in some embodiments, some or all of a fuse system having one or more features as described herein can be implemented on a semiconductor die.

FIG. 3 shows an example embodiment of a fuse sensing circuit coupled to a fuse.

FIG. 4 shows that in some embodiments, an output circuit of the fuse system of FIG. 1 can be implemented as a set-reset (SR) latch circuit.

FIGS. 5A and 5B show an example in which the fuse of FIG. 3 is in an intact state.

FIGS. 6A and 6B show an example in which the fuse of FIG. 3 is in a blown state.

FIGS. 7A-7D show examples of various timing diagrams associated with sensing of a fuse in an intact state, such as in the example of FIGS. 5A and 5B.

FIGS. 8A-8D show examples of various timing diagrams associated with sensing of a fuse in a blown state, such as in the example of FIGS. 6A and 6B.

FIG. 9A shows various measured timing traces corresponding to the timing diagrams of FIGS. 7A-7D.

FIG. 9B shows various measured currents and voltages associated with the measured timing traces of FIG. 9A.

FIG. 10A shows various measured timing traces corresponding to the timing diagrams of FIGS. 8A-8D.

FIG. 10B shows various measured currents and voltages associated with the measured timing traces of FIG. 10A.

FIG. 11 depicts a transistor that can be utilized in the sensing current control block of FIG. 3.

FIG. 12 shows that a current through the transistor of FIG. 11 can increase as the device size increases.

FIG. 13 depicts an example of a detection margin as a function of device size.

FIG. 14 shows example values of a fuse state output for a fuse in an intact state, when the device size of a transistor is varied.

FIG. 15 shows examples related to a failure of fuse sensing reliability at smaller device sizes.

FIG. 16 shows another example values of a fuse state output for a fuse in an intact state, when the device size of a transistor is varied.

FIG. 17 show an example of how a range of device size can be selected to provide a reduced device size and a reduced device current.

FIG. 18 shows an example of how the configuration of FIG. 17 can be implemented such that the device size range or value is sufficiently spaced from the detection margin threshold value.

FIG. 19 shows an example of a variation to the example fuse sensing configuration of FIG. 3.

FIG. 20 shows another example of a variation to the example fuse sensing configuration of FIG. 3.

FIG. 21 shows examples of output currents and voltages for device width values similar to the example of FIG. 15.

FIG. 22 shows that in some embodiments, a fuse system having one or more features as described herein can be implemented in an electronic system for initializing and/or resetting one or more integrated circuits.

FIG. 23 shows that in some embodiments, the electronic system of FIG. 22 can be a radio-frequency (RF) system.

FIG. 24 shows that in some embodiments, a fuse system having one or more features as described herein can be implemented in an electronic module.

FIG. 25 shows that in some embodiments, a fuse system having one or more features as described herein can be implemented in an RF module.

FIGS. 26A-26D show RF modules that can be more specific examples of the RF module of FIG. 25.

FIG. 27 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

In many integrated circuit devices, fuses are widely utilized to store values to provide useful information. For example, fuse-stored values can provide information about part-to-part and/or process variations among different devices such as integrated circuit die. With such information, a given integrated circuit die can be operated appropriately to provide improved or desired performance. In another example, fuse-stored values can be utilized as unique codes to provide, for example, security functionality.

In some embodiments, a fuse sensing circuit can be implemented to operate reliably over different process corners associated with integrated circuit die. Further, an integrated circuit die can include multiple fuses (e.g., greater than 50). Thus, it is desirable to have a fuse sensing circuit be relatively compact to allow the corresponding die to also be more compact. It is also desirable to have a fuse sensing circuit have smaller transient current consumption to allow the corresponding die to be more power efficient.

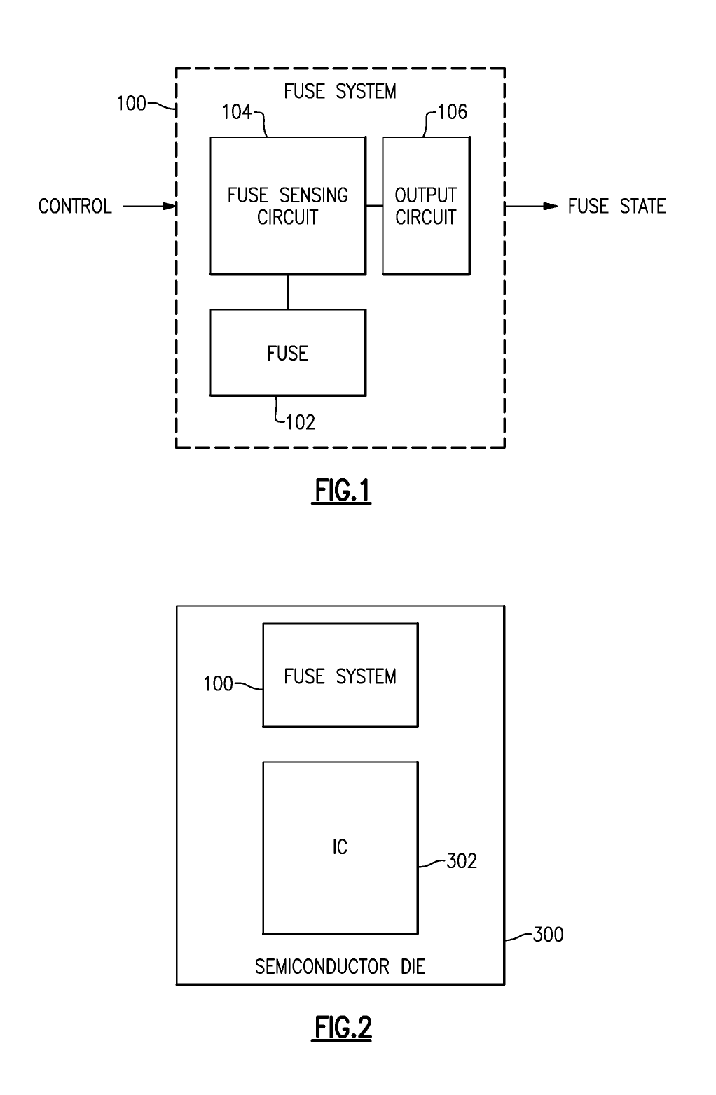

FIG. 1 depicts a fuse sensing circuit 104 that can provide some or all of the foregoing desirable functionalities. In some embodiments, such a fuse sensing circuit can be part of a fuse system 100 configured to receive a control signal (Control) and generate an output having a fuse state for a fuse 102. Such a fuse is depicted as being coupled to the fuse sensing circuit 104 so as to allow the fuse sensing circuit 104 to detect the state of the fuse 102. In some embodiments, such a detected state of the fuse 102 can be processed by an output circuit 106 to provide the output of the fuse state (Fuse State). Examples related to such a fuse system are described herein in greater detail.

FIG. 2 shows that in some embodiments, some or all of a fuse system 100 having one or more features as described herein can be implemented on a semiconductor die 300. Such a semiconductor die can also include an integrated circuit 302 that utilizes the fuse system 100. In some embodiments, a fuse associated with the fuse system 100 can be formed as part of the die 300, and substantially all of a fuse sensing circuit (104 in FIG. 1) of the fuse system 100 can also be implemented on the die 300.

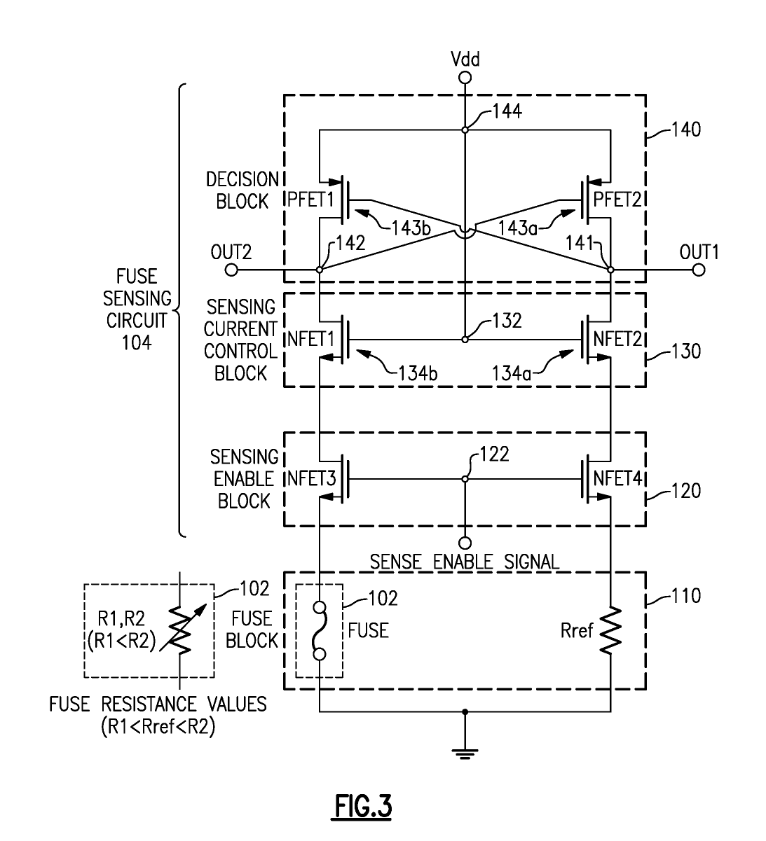

FIG. 3 shows an example embodiment of a fuse sensing circuit 104 coupled to a fuse 102. For the purpose of description, it will be understood that such a fuse is implemented on a semiconductor die and configured to be in a first state (e.g., intact state) or a second state (e.g., blown state).

In some embodiments, the fuse 102 and a reference resistance (e.g., a resistor) Rref can form a fuse block 110. The fuse 102 can have a first resistance R1 in the intact state, and a second resistance R2 in the blown state. Thus, the fuse 102 can be represented as a variable resistor having two resistance values R1, R2. Typically, the second resistance R2 associated with the blown state is greater than the first resistance R1 associated with the intact state.

In some embodiments, the reference resistance Rref can be selected to have a value between the values of R1 and R2, such that R1<Rref<R2. Since the reference resistance Rref is utilized as a reference value to distinguish between the values of R1 and R2, Rref can be selected to be sufficiently separated from each of R1 and R2. For example, Rref can be selected to be about halfway between R1 and R2 (e.g., Rref=(R1+R2)/2).

In the example of FIG. 3, the fuse 102 is shown to be implemented along a first path between a voltage node Vdd and ground, and the reference resistance Rref is shown to be implemented along a second path that is generally electrically parallel with the first path. From the voltage node Vdd, the first path is shown to include transistors PFET1, NFET1, NFET3 and the fuse 102 arranged in series to the ground. The source of the transistor PFET1 is shown to be connected to the voltage node Vdd, and the drain of the transistor PFET1 is shown to be connected to the drain of the transistor NFET1. The source of the transistor NFET1 is shown to be connected to the drain of the transistor NFET3, and the source of the transistor NFET3 is shown to be connected to one side of the fuse 102. The other side of the fuse 102 is shown to be connected to the ground.

Similarly, from the voltage node Vdd, the second path is shown to include transistors PFET2, NFET2, NFET4 and the reference resistance Rref arranged in series to the ground. The source of the transistor PFET2 is shown to be connected to the voltage node Vdd, and the drain of the transistor PFET2 is shown to be connected to the drain of the transistor NFET2. The source of the transistor NFET2 is shown to be connected to the drain of the transistor NFET4, and the source of the transistor NFET4 is shown to be connected to one side of the reference resistance Rref. The other side of the reference resistance Rref is shown to be connected to the ground.

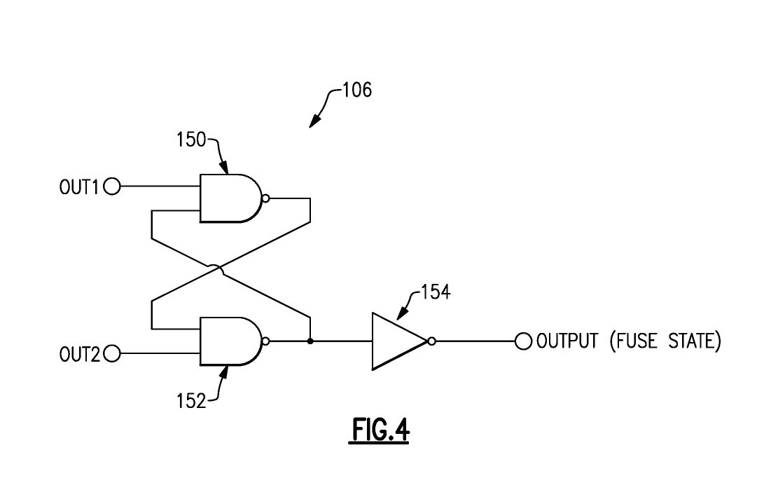

In the example of FIG. 3, the transistors PFET1 and PFET2 are collectively indicated as a decision block 140. In some embodiments, such a decision block can be implemented as a cross-coupled decision block. For example, the gate of the transistor PFET1 (143b) is shown to be coupled to the drain of the transistor PFET2 (143a) and define a first output node 141 (Out1), and the gate of the transistor PFET2 (143a) is shown to be coupled to the drain of the transistor PFET1 (143b) and define a second output node 142 (Out2). An example of how such first and second outputs of the decision block 140 can be processed is described herein in reference to FIG. 4.

In the example of FIG. 3, the transistors NFET1 and NFET2 are collectively indicated as a sensing current control block 130. In some embodiments, such a sensing current control block can be configured to control transient current associated with sensing operation of the fuse sensing circuit 104. In the example of FIG. 3, the gate of the transistor NFET1 (134b) is shown to be coupled with the gate of the transistor NFET2 (134a) to define a common gate node 132. Such a common gate node (132) is shown to be coupled to the voltage node Vdd (also indicated as 144), such that gates of the transistors NFET1 and NFET2 can receive a common gate voltage from the voltage node Vdd. Examples of how such transistors (NFET1, NFET2) can be configured are described herein in greater detail.

In the example of FIG. 3, the transistors NFET3 and NFET4 are collectively indicated as a sensing enable block 120. More particularly, the gate of the transistor NFET3 is shown to be coupled with the gate of the transistor NFET4 to define a common gate node 122. Such a common gate node (122) is shown to be configured to receive a sense enable signal, such that gates of the transistors NFET3 and NFET4 can receive a common sense enable signal to allow transient currents to pass through the first and second paths associated with the fuse 102 and the reference resistance Rref, respectively.

In the example of FIG. 3, the transistors PFET1 and PFET2 are p-type field-effect transistors (FETs), and the transistors NFET1, NFET2, NFET3 and NFET4 are n-type FETs. However, it will be understood that one or more features of the present disclosure can also be implemented with other types of FETs for some or all of the foregoing transistors. It will also be understood that one or more features of the present disclosure can also be implemented utilizing other types of transistors, including bipolar-junction transistors.

In some embodiments, the transistors PFET1, PFET2, NFET1, NFET2, NFET3 and NFET4 can be implemented as, for example, silicon-on-insulator (SOI) devices. It will be understood that such transistors can also be implemented as other types of semiconductor devices.

FIG. 4 shows that in some embodiments, the output circuit 106 of FIG. 1 can be implemented as a set-reset (SR) latch circuit 106. Such an SR latch circuit can include first and second NAND gates 150, 152 and an inverter 154 arranged as shown.

More particularly, the first NAND gate 150 can receive, as an input, the first output (Out1) of the decision block 140 of FIG. 3 (from node 141). Similarly, the second NAND gate 152 can receive, as an input, the second output (Out2) of the decision block 140 of FIG. 3 (from node 142). The output of the first NAND gate 150 can be provided as the other input of the second NAND gate 152, and the output of the second NAND gate 152 can be provided as the other input of the first NAND gate 150.

The output of the second NAND gate 152 can be provided as an input of the inverter 154, and an output of the inverter 154 can be utilized as an output of the fuse system (100 in FIG. 1). Such an output can include information about the fuse state (e.g., intact state or blown state).

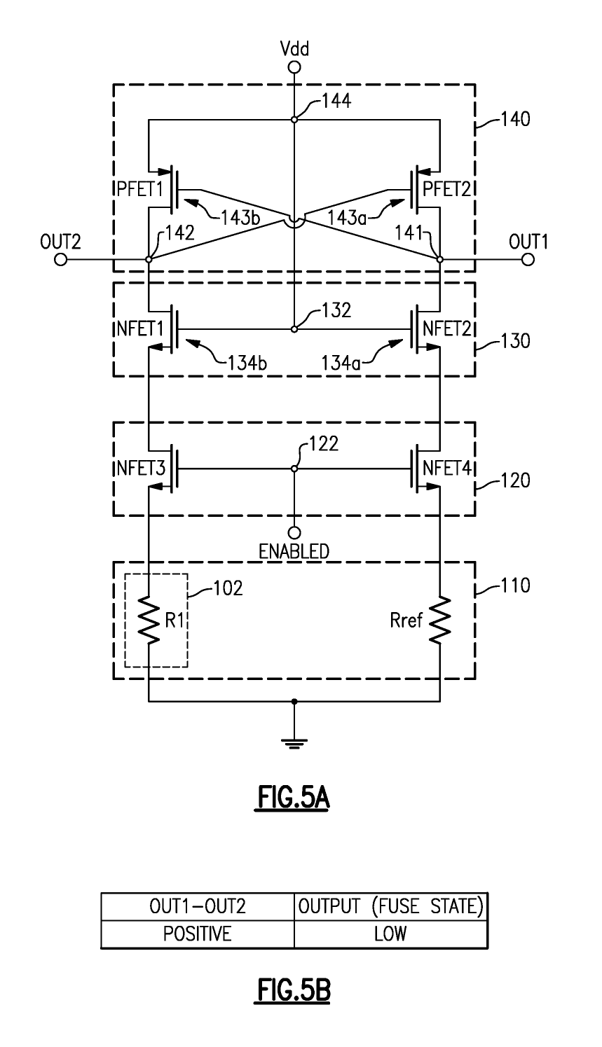

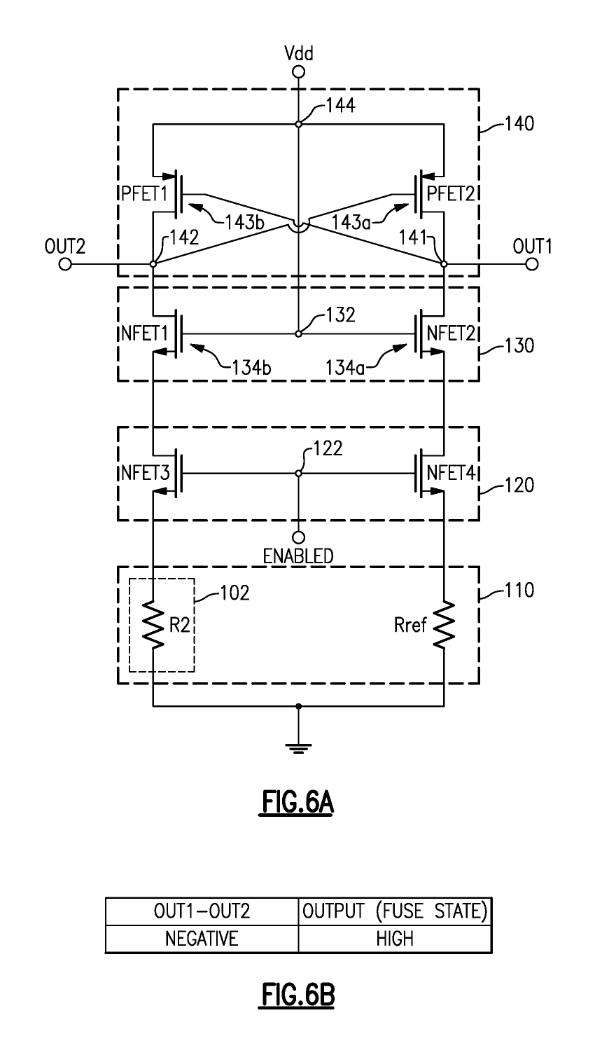

FIGS. 5A and 5B show an example in which the fuse 102 of FIG. 3 is in the intact state (with resistance R1). FIGS. 6A and 6B show an example in which the fuse 102 of FIG. 3 is in the blown state (with resistance R2).

In FIGS. 5A and 5B, the sensing enable block (120 in FIG. 3) is shown to be enabled such that each of the transistors NFET3 and NFET4 is provided with an enable gate voltage so as to allow the respective transient current to pass between the voltage node Vdd and the ground. The fuse 102 is in its intact state, such that its resistance R1 is less than the reference resistance Rref. Accordingly, the first output (Out1) of the decision block (140 in FIG. 3) has a magnitude that is greater than a magnitude of the second output (Out2), such that a difference Out1−Out2 has a positive value. With such outputs (Out1, Out2) of the decision block 140, the SR latch circuit (106 in FIG. 4) generates a logic-low output (Output) to indicate that the fuse state is intact.

In FIGS. 6A and 6B, the sensing enable block (120 in FIG. 3) is shown to be enabled such that each of the transistors NFET3 and NFET4 is provided with an enable gate voltage so as to allow the respective transient current to pass between the voltage node Vdd and the ground. The fuse 102 is in its blown state, such that its resistance R2 is greater than the reference resistance Rref. Accordingly, the first output (Out1) of the decision block (140 in FIG. 3) has a magnitude that is less than a magnitude of the second output (Out2), such that a difference Out1−Out2 has a negative value. With such outputs (Out1, Out2) of the decision block 140, the SR latch circuit (106 in FIG. 4) generates a logic-high output (Output) to indicate that the fuse state is blown.

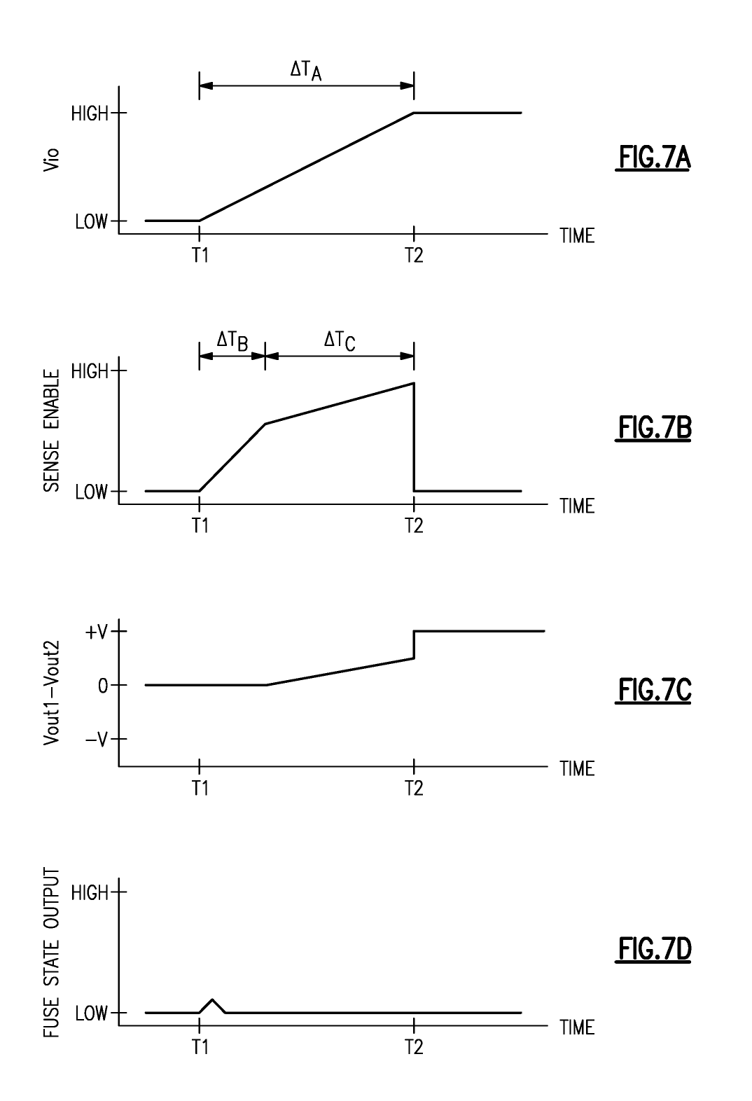

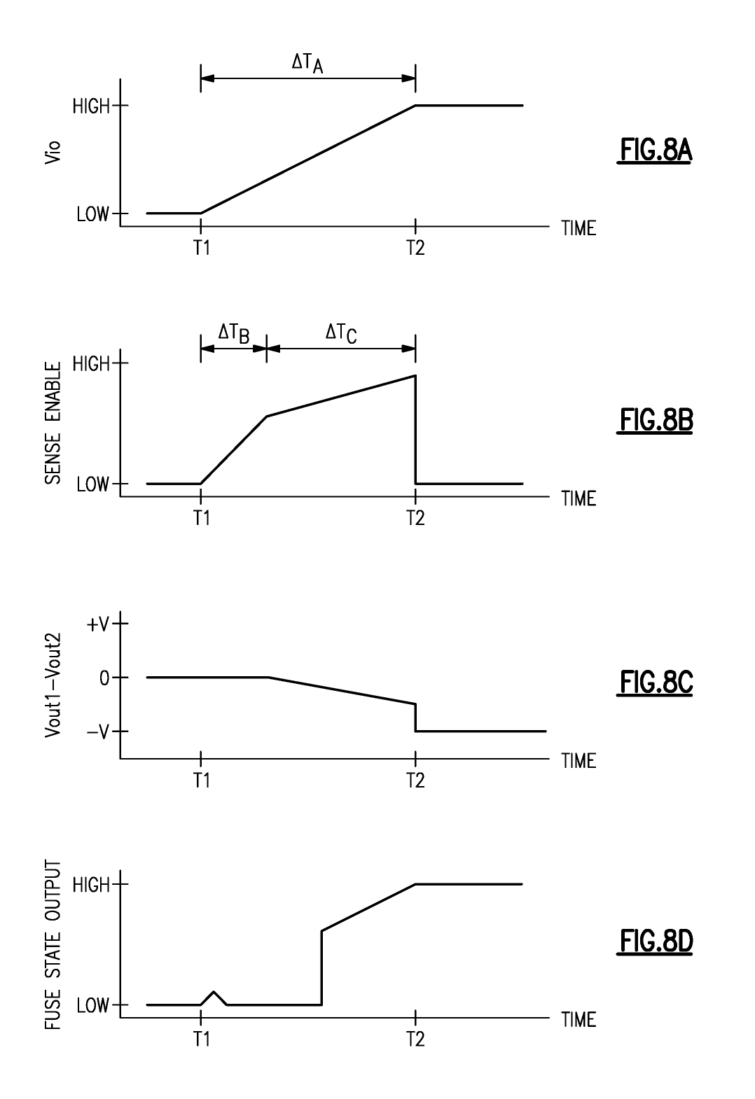

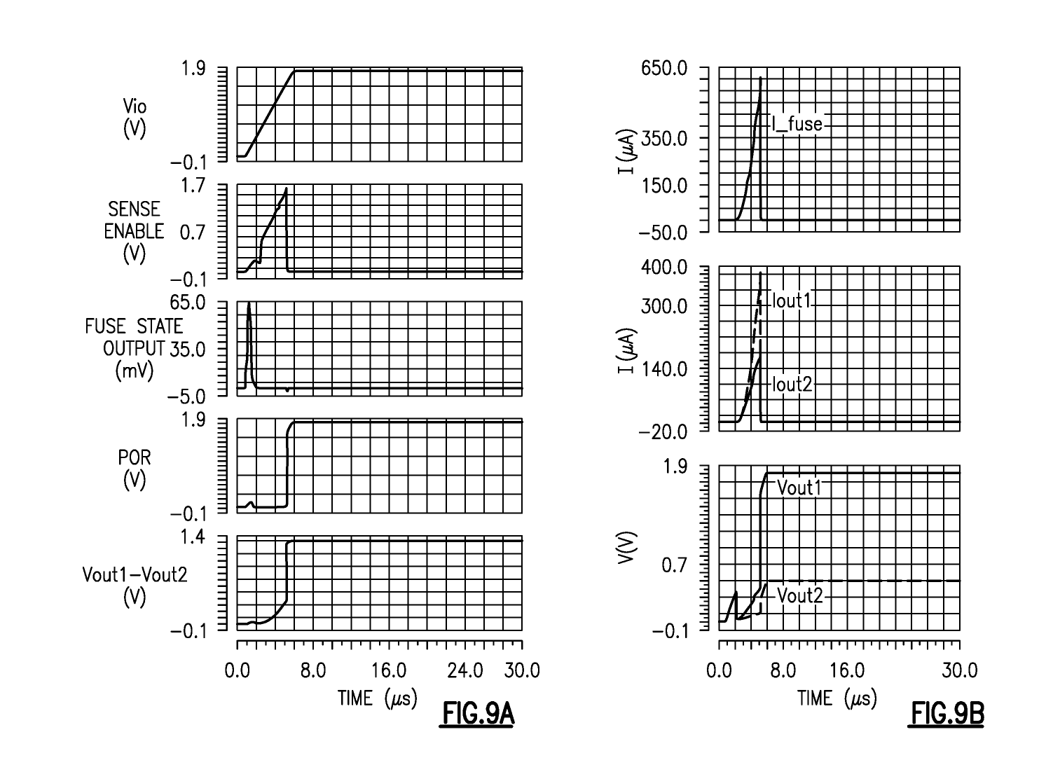

FIGS. 7A-7D show examples of various timing diagrams associated with sensing of a fuse in an intact state (e.g., as in the example of FIGS. 5A and 5B). FIGS. 8A-8D show examples of various timing diagrams associated with sensing of a fuse in a blown state (e.g., as in the example of FIGS. 6A and 6B).

In some embodiments, operation of the fuse sensing circuit 104 of FIGS. 3, 5A and 6A can be based on a ramp-up of a known supply voltage such as a secondary supply voltage Vio. Such a ramp-up of Vio can be implemented whenever a reset (e.g., power on reset (POR)) is desired. During such a reset, states of various fuses can be sensed as described herein to allow a related integrated circuit to be configured appropriately.

Accordingly, in each of FIGS. 7A and 8A, Vio begins to ramp up at time T1, from a low value to a high value which is reached at time T2. Such a ramp-up is shown to last for a duration of ΔT_{A}. During the ramp-up of Vio, or when Vio reaches the high value, a POR signal can transition from a low state to a high state, and such a high state of POR can be utilized to perform various reset functions.

In some embodiments, the supply voltage (e.g., Vdd provided at the supply node 144 in FIG. 3) can be provided by Vio, or substantially track Vio. It will be understood that in some embodiments, the supply voltage can be provided by another source.

In some embodiments, a P̅O̅R̅ (POR-bar) signal can be obtained from the foregoing Vio and POR, and such a P̅O̅R̅ can be utilized as a sense enable signal provided to the sense enable node (e.g., 122 in FIG. 3). Accordingly, in each of FIGS. 7B and 8B, the sense enable (P̅O̅R̅) signal is shown to transition between a low state and a high state, approximately between times T1 and T2. In the example shown, such a transition of the sense enable (P̅O̅R̅) signal is shown to include a first portion having a first slope during a time duration of ΔT_{B}, and a second portion having a second slope during a time duration of ΔT_{C}. In the example, the first slope is greater than the second slope. At approximately time T2, the sense enable (P̅O̅R̅) signal is shown to sharply transition back down to the low state when the POR signal goes high.

When the sense enable (P̅O̅R̅) signal reaches a sufficiently high value, transient currents can flow through the sensing enable transistors NFET3 (for the fuse 102) and NFET4 (for the reference resistance Rref) to thereby generate a non-zero difference between voltages at the output nodes Out1, Out2. Such a voltage difference is also described herein as Out1−Out2, and can be positive (e.g., when the fuse is intact) or negative (e.g., when the fuse is blown).

In FIGS. 7C and 8C, such a voltage difference (Out1−Out2) is depicted as Vout1−Vout2, and can change from a value of approximately zero to a positive value (e.g., +V) or a negative value (e.g., −V). In FIG. 7C, the fuse is in an intact state; thus, Vout1−Vout2 becomes positive as the sense enable (P̅O̅R̅) signal transitions to a high state. For example, Vout1−Vout2 is shown to remain at approximately zero for some time after time T1 (when the sense enable (P̅O̅R̅) signal begins increasing), and then begins to increase until approximately time T2 is reached. At such a time, Vout1−Vout2 is shown to jump sharply to the positive value (+V).

In FIG. 8C, the fuse is in a blown state; thus, Vout1−Vout2 becomes negative as the sense enable (P̅O̅R̅) signal transitions to a high state. For example, Vout1−Vout2 is shown to remain at approximately zero for some time after time T1 (when the sense enable (P̅O̅R̅) signal begins increasing), and then begins to decrease until approximately time T2 is reached. At such a time, Vout1−Vout2 is shown to fall sharply to the negative value (−V).

As described herein, the first and second output voltages Vout1, Vout2 (also referred to herein as Out1, Out2) can be utilized by the output circuit 106 of FIG. 4 (e.g., a set-reset (SR) latch circuit) to generate an output signal representative of the state of the sensed fuse. As also described herein in reference to FIGS. 5 and 6, such an output signal can be low when the fuse is intact, and high when the fuse is blown.

In FIGS. 7D and 8D, such fuse state output signals are depicted. In FIG. 7D in which the fuse is in the intact state, the fuse state output is shown to begin in the low state at time T1, and remain in the low state at time T2. In FIG. 8D in which the fuse is in the blown state, the fuse state output is shown to begin in the low state as in the example of FIG. 7D, and then transition sharply upward at a time between T1 and T2. From such an upward value, the fuse state output continues to increase until it reaches the high value at approximately T2.

In some embodiments, determination that the fuse is in the blown state can be made even if the full high value is not reached at T2 by the fuse state output signal. For example, a fuse state output value between the sharply increased value (at time between T1 and T2) and the full high value (at approximately T2) can be utilized to determine that the fuse is in the blown state. Similarly, a fuse state output value remaining at the low value after the same time (between T1 and T2) can be utilized to determine that the fuse is in the intact state.

Based on the foregoing examples of timing diagrams, one can see that the fuse state output signal can be sufficiently low (as in FIG. 7D when the fuse is intact) or sufficiently high (as in FIG. 8D when the fuse is blown) to allow determination of the fuse state before the end of the Vio ramp-up period (at time T2). Thus, one can see that the fuse sensing circuit 104 of FIG. 3 can allow fuse states to be determined quickly and efficiently.

FIG. 9A shows various measured timing traces corresponding to the timing diagrams of FIGS. 7A-7D (sensing of a fuse in an intact state as in the example of FIGS. 5A and 5B). FIG. 9A also shows a measured POR timing trace.

FIG. 9B shows various measured currents and voltages associated with the measured timing traces of FIG. 9A. More particularly, the upper panel shows a total transient current (I_fuse) measured from the power supply of the fuse sensing circuit (when the fuse is in the intact state), with I_fuse generally tracking the sense enable voltage trace of FIG. 9A. The middle panel shows measured currents at the fuse (Iout1) and the reference resistance Rref (Iout2). The lower panel shows measured voltages at the first output (Vout1) and the second output (Vout2). Since the fuse is in the intact state, Vout1>Vout2 when the fuse sensing circuit is sufficiently enabled. Accordingly, Iout1 is greater than Iout2 during the ramping period.

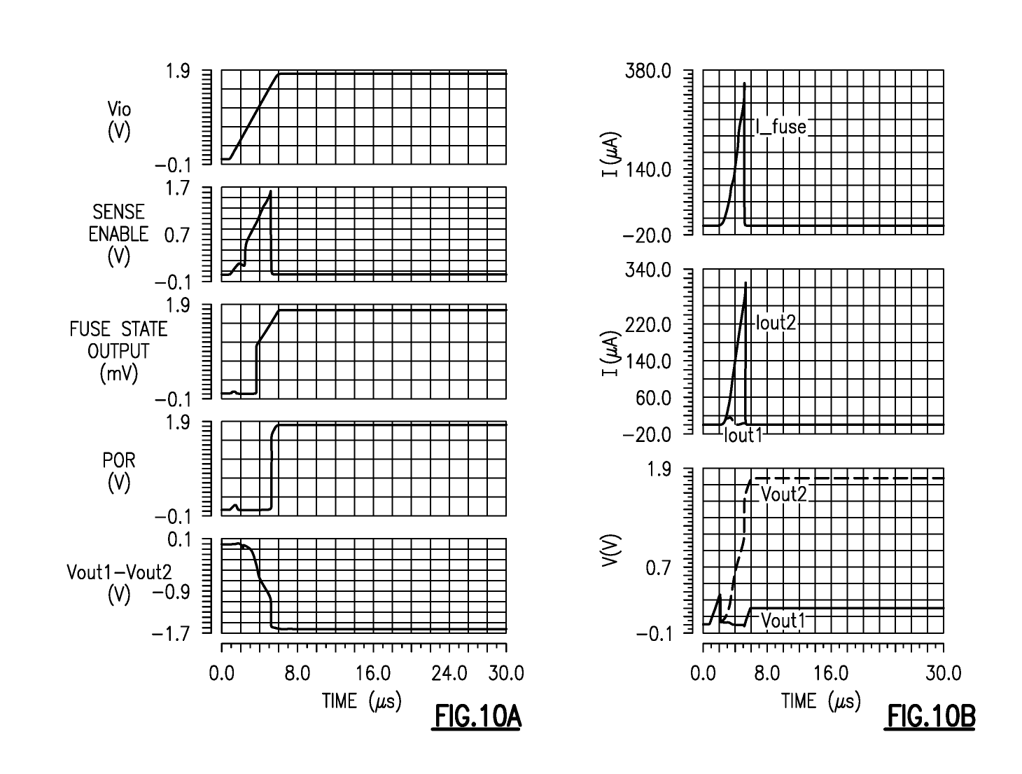

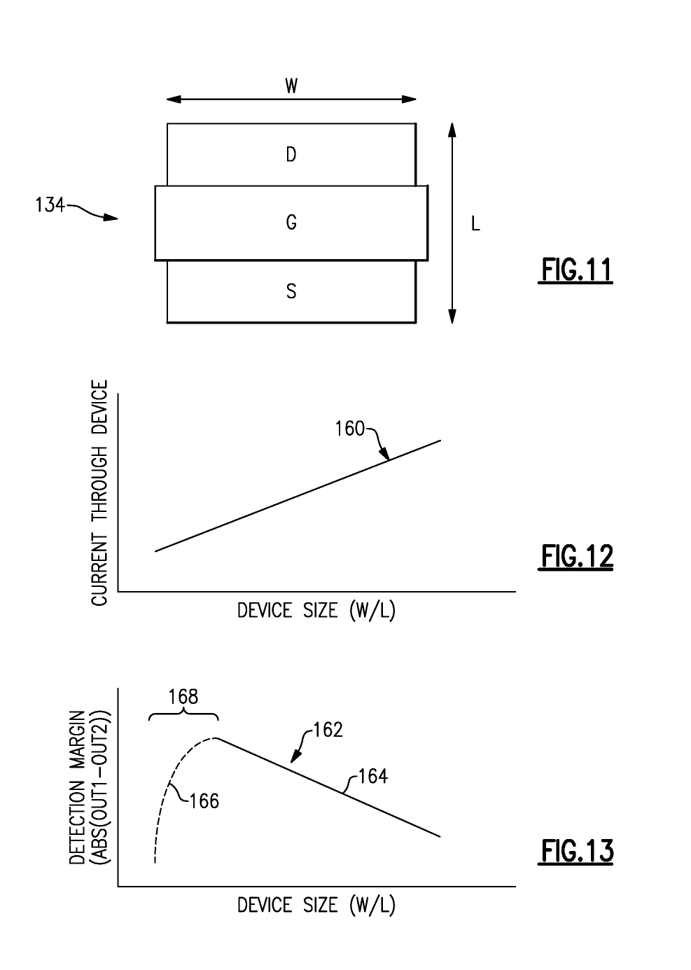

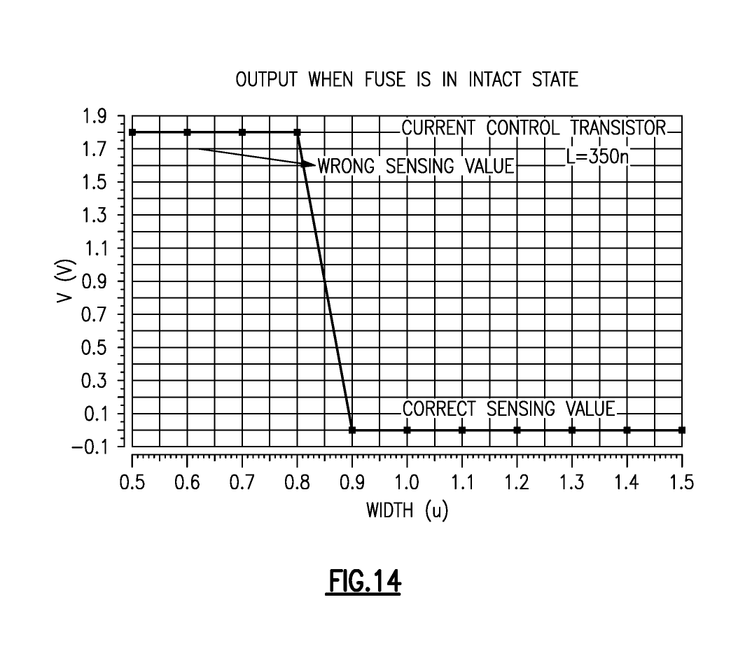

FIG. 10A shows various measured timing traces corresponding to the timing diagrams of FIGS. 8A-8D (sensing of a fuse in a blown state as in the example of FIGS. 6A and 6B). FIG. 10A also shows a measured POR timing trace.

FIG. 10B shows various measured currents and voltages associated with the measured timing traces of FIG. 10A. More particularly, the upper panel shows a total transient current (I_fuse) measured from the power supply of the fuse sensing circuit (when the fuse is in the blown state), with I_fuse generally tracking the sense enable voltage trace of FIG. 10A. The middle panel shows measured currents at the fuse (Iout1) and the reference resistance Rref (Iout2). The lower panel shows measured voltages at the first output (Vout1) and the second output (Vout2). Since the fuse is in the blown state, Vout2>Vout1 when the fuse sensing circuit is sufficiently enabled. Accordingly, Iout2 is greater than Iout1 during the ramping period.

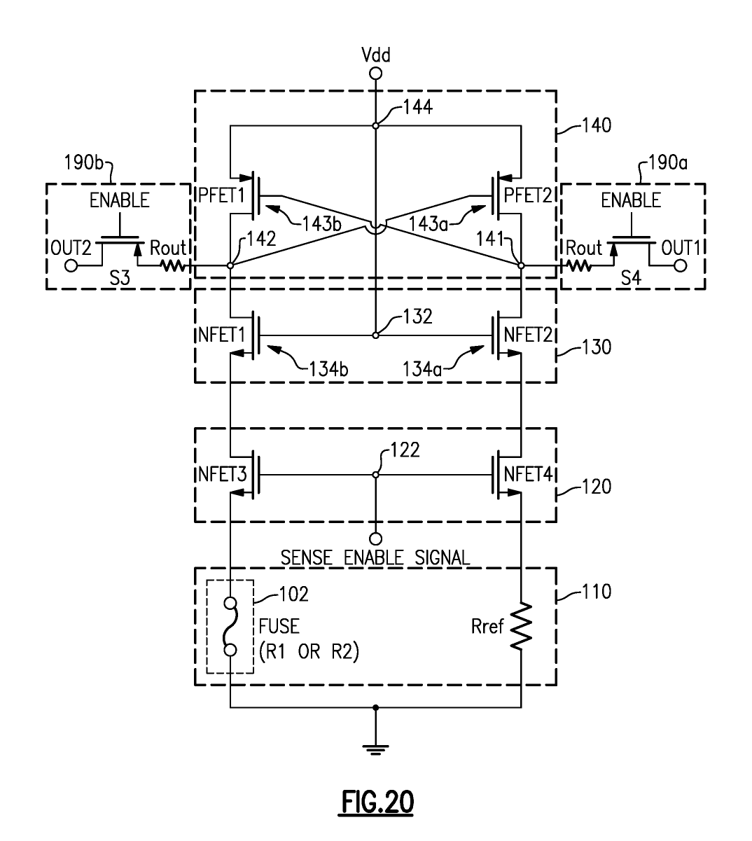

Referring to the examples of FIGS. 9B and 10B, it is noted that the measured current traces (I_fuse, Iout1, Iout2) generally track the sense enable signal, such that the current traces sharply drop to approximately zero when the sense enable signal is turned off. However, the measured voltages Vout1 and Vout2 are shown to maintain their corresponding state voltages after the sense enable signal is turned off. An example of how such voltages can be maintained is described herein in greater detail in reference to FIG. 19.

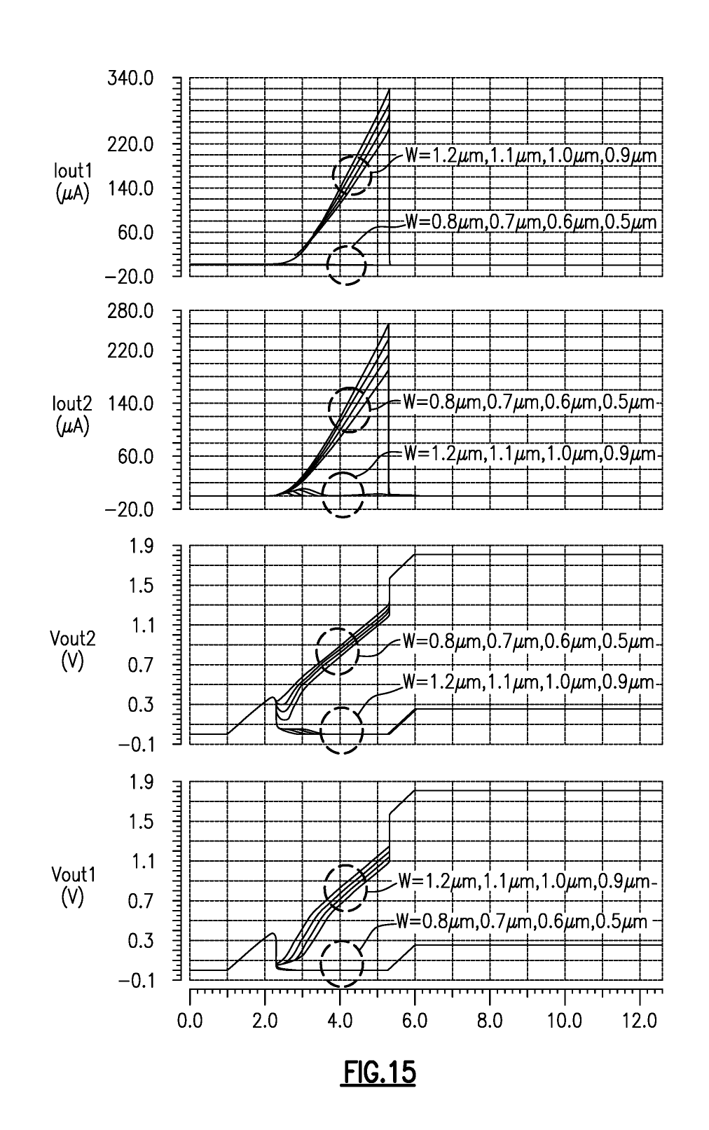

As described in reference to FIGS. 7-10, sufficient amount of difference between Vout1 and Vout2 is needed or desired to reliably produce a proper fuse state output. Additionally, it is preferable to have the fuse sensing circuit utilize reduced current and space. FIGS. 11-18 show various examples of how such design considerations can be implemented to provide a fuse sensing circuit that can use reduced current, be implemented as a device having one or more reduced dimensions, and/or be reliable.

FIG. 11 depicts a transistor 134 that can be utilized in the sensing current control block 130 of FIG. 3. Such a transistor can be implemented for each of the transistors NFET1 and NFET2 (134b and 134a in FIG. 3). For the purpose of description, such a transistor can be represented as a rectangular shaped device having an active region with a width W and a length L. On such an active region, drain (D), source (S) and gate (G) contacts can be implemented to allow current to flow between the drain and source when an appropriate gate voltage is applied.

As is generally understood, a larger dimensioned transistor typically allows greater amount of current to flow. Such dependence of current flow on transistor dimension can be due to, for example, variation of on-resistance (Ron) of the transistor as a function of dimension. For example, a larger width transistor will have a lower on-resistance than a smaller width transistor, assuming that both transistors have same length dimensions.

Thus, and as shown in FIG. 12, a current (plot 160) through the transistor 134 of FIG. 11 is shown to increase as the device size (e.g., W/L, for a given value of L) increases. In such a context, implementing a reduced device size W/L is desirable because the device is smaller, and also because of the reduced current.

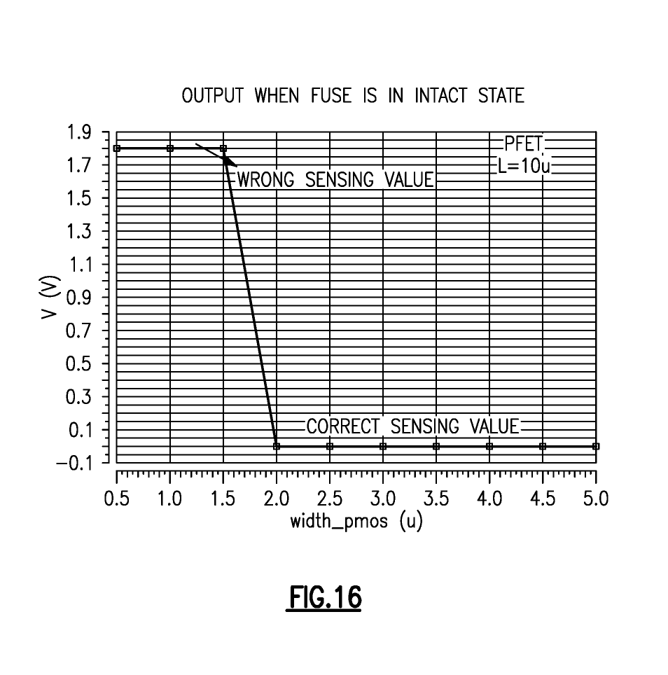

However, reduction of the device size W/L beyond some value can lead to failure or reduction of fuse sensing reliability. For example, FIG. 13 depicts a detection margin (plot 162) (which for the purpose of description can be defined as an absolute value of the difference between Vout1 and Vout2 (also referred to as Out1 and Out2)) as a function of device size W/L. In such a relationship, one can see that as the device size W/L decreases, the detection margin increases in the portion 164, which is generally desirable. However, when the device size continues to decrease beyond some value of W/L into a region indicated as 168, the detection margin decreases sharply, as indicated by the portion 166. With such a sharp decrease in detection margin, fuse sensing reliability also decreases rapidly. Examples related to such fuse sensing reliability are described herein in greater detail.

FIG. 14 shows values of a fuse state output (e.g., as in the example of FIG. 7D) for a fuse in an intact state, when the device size W/L of a transistor (134 in FIG. 11, 134a or 134b in FIG. 3) is varied. In the example of FIG. 14, the length dimension (L) of the device is at a value of 0.350 μm, and the width dimension (D) of the device is varied from 1.5 μm to 0.5 μm in 0.1 μm steps.

As described herein in reference to FIGS. 7D and 9A, the fuse being in the intact state should result in the example fuse state output being in a low state (e.g., approximately 0V). In the example of FIG. 14, such a correct fuse state output value of 0V is observed for values of D greater than or equal to 0.9 μm. However, for values of D less than 0.9 μm, an incorrect value is generated for the fuse state output value (e.g., a high state value at approximately 1.8V).

FIG. 15 shows additional examples related to the foregoing failure of fuse sensing reliability at smaller device sizes. In FIG. 15, traces of currents Iout1, Iout2 and voltages Vout1, Vout2 at the outputs Out1, Out2 are shown (similar to the example of FIGS. 9A and 9B) for some of the various device dimensions of FIG. 14. As described in reference to FIGS. 9A and 9B, Iout1 should be generally greater than Iout2 during the ramping period, and Vout1 should also be greater than Vout2, when the fuse is in the intact state.

Referring to the Iout1 and Iout2 plots the example of FIG. 15, one can see that Iout1 is indeed greater than Iout2 for the device width values W=1.2 μm, 1.1 μm, 1.0 μm and 0.9 μm. However, for device width values W=0.8 μm, 0.7 μm, 0.6 μm and 0.5 μm, Iout1 is less than Iout2.

Referring to the Vout1 and Vout2 plots in the example of FIG. 15, one can see that Vout1 is indeed greater than Vout2 for the device width values W=1.2 μm, 1.1 μm, 1.0 μm and 0.9 μm. However, for device width values W=0.8 μm, 0.7 μm, 0.6 μm and 0.5 μm, Vout1 is less than Vout2, thereby contributing to the wrong fuse state output value.

FIG. 16 shows another example of fuse state output (e.g., as in the example of FIG. 7D) values for a fuse in an intact state, when the device size W/L of a transistor (134 in FIG. 11, 134a or 134b in FIG. 3) is varied. In the example of FIG. 16, the length dimension (L) of the device is at an example value of 10 μm (which is significantly larger than the example of FIG. 14), and the width dimension (D) of the device is varied from 5.0 μm to 0.5 μm in 0.5 μm steps.

Similar to the example of FIG. 14, one can see that the fuse state output value turns into a wrong value when the width dimension D is less than 2.0 pm. It is noted that such a threshold value is about twice larger than the example threshold value of 0.9 μm in the example of FIG. 14. However, in the example of FIG. 16, the length L of the device (10 μm) is much larger than the length L of 0.350 μm in the example of FIG. 14. Thus, one can see that either or both of the length dimension L and the width dimension D can be adjusted to accommodate some or all of fuse sensing reliability, device dimension, and device current.

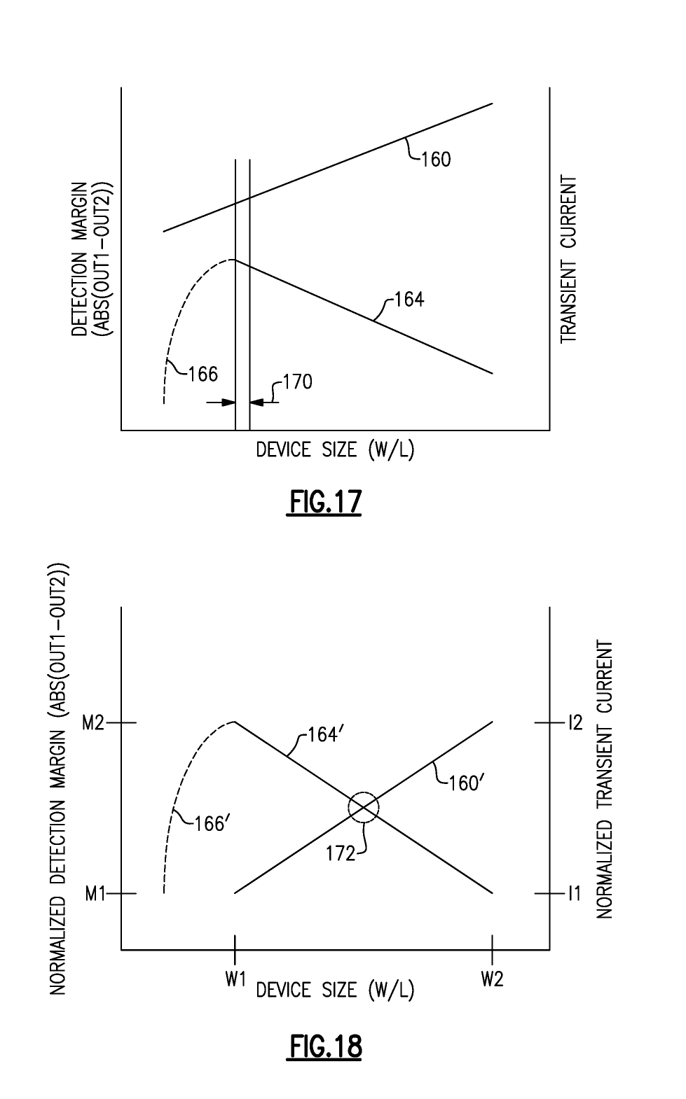

FIG. 17 show an example of how a range 170 of device size W/L (e.g., for a given length L) can be selected to provide a reduced device size and a reduced device current. Plot indicated as 160 is for transient current in the device (e.g., transistor 134 in FIG. 11, 134a or 134b in FIG. 3), similar to the example of FIG. 12, and plot that includes portions 164 and 166 is for detection margin, similar to the example of FIG. 13.

In the example of FIG. 17, the range 170 of device size W/L can be selected to include the lower limit of the device size W/L (in the portion 164) before the detection margin breaks down rapidly (portion 166). Such a range can provide the smallest device size and the smallest transient current while providing acceptable fuse sensing reliability.

In some applications, having a device size so close to the detection margin breakdown may not be desirable, since there is very little margin in device size before fuse sensing reliability can change rapidly. Accordingly, in some embodiments, a device size range or value can be moved away from the detection margin threshold value so as to provide sufficient safety margin in device size. While such a device size range or value will be larger than the example of FIG. 17, and also have larger transient current, the presence of a larger device size margin (before breakdown in fuse sensing reliability) can be desirable.

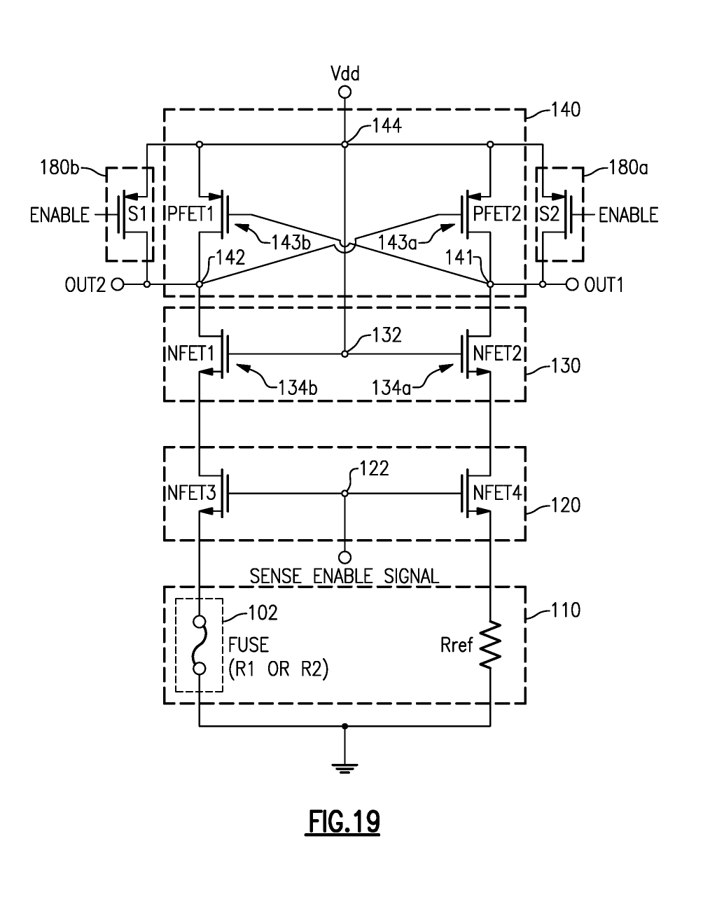

FIG. 18 shows an example of how the foregoing configuration can be implemented such that the device size range or value is sufficiently spaced from the detection margin threshold value. For the purpose of description of FIG. 18, it will be assumed that the device length L has a given value. Suppose that W1 is a lower limit of device width range in which detection margin can be generated as desired. Also suppose that W2 is an upper limit of device width determined by, for example, device design.

Such a range of device width (W1 to W2) yields a range of detection margin values, and such a range of detection margin values can be normalized appropriately to provide a range of M1 to M2 (corresponding to a normalized portion 164′). Similarly, such a range of device width (W1 to W2) yields a range of transient current values, and such a range of transient current values can be normalized appropriately to provide a range of I1 to I2 (corresponding to a normalized plot 160′).

In some embodiments, a crossing point 172 of such normalized detection margin plot 164′ and normalized transient current plot 160′ can be used as a width selected for the device. One can see that such a device width provides ample margin in the width dimension before the fuse sensing reliability breaks down.

Referring to the examples of FIGS. 17 and 18, it is noted that relative positions of the plots 160 and 164 (in FIG. 17) and the plots 160′ and 164′ (in FIG. 18) depend on vertical scale values. For example, if another scale is used for the transient current in FIG. 17, the plot 160 can be higher than, lower than, or intersect with the detection margin plot 164. Accordingly, normalization of the two vertical scales as in FIG. 18 can provide a more general method of determining the crossing point 172. For example, vertical scales for the normalized detection margin and the normalized transient current can be set to have equal position and spacing when plotted on their respective vertical axes.

In some embodiments, a device size width W (for a given length L) can be selected in other manners. For example, suppose there is a range of width (such as a range from W1 to W2 in FIG. 18) in which fuse sensing can be achieved reliably. In such a context, one can define a device width margin as being 0% when a selected width W_{selected} is at W1, and 100% when W_{selected} is at W2. In some embodiments, the selected width W_{selected} can provide a device width margin of, for example, zero or more percent, at least 1%, at least 5%, at least 10%, at least 20%, at least 30%, at least 40%, or at least 50%. In some embodiments, the selected width W_{selected} can provide a device width margin that is in a range of, for example, 0% to 10%, 10% to 20%, 20% to 30%, 30% to 40%, or 40% to 50%.

FIG. 19 shows a variation to the fuse sensing configuration of FIG. 3. In the example of FIG. 19, the decision block 140, the sensing current control block 130, and the sensing enable block 120 can be similar to the corresponding blocks in the configuration of FIG. 3.

In the example of FIG. 19, each of the output nodes Out1, Out2 can be switchably coupled to the voltage node Vdd (144). For example, a first switch S2 (e.g., a PFET) (180a) can be implemented to be electrically parallel with PFET2 (143a), and a second switch S1 (e.g., a PFET) (180b) can be implemented to be electrically parallel with PFET1 (143b). Each of the first and second switches S2, S1 can be turned on by application of an enable signal, and be turned off by removal of such an enable signal.

In some embodiments, a P̅O̅R̅ (POR-bar) signal can be utilized to enable or disable each of the first and second switches S2, S1. As described herein in reference to FIGS. 7-10, a P̅O̅R̅ signal can be used as a sense enable signal for the sensing enable block 120. Such a P̅O̅R̅ signal is shown to return to the low state (e.g., at approximately time T2) once the sensing process is accomplished.

In the example of FIG. 19, the enable signal provided to the first and second switches S2, S1 can be based on the same P̅O̅R̅ signal. For example, the enable signal to each of S2 and S1 can be high when the P̅O̅R̅ signal is ramping up (and the fuse sensing is being achieved), and low when the P̅O̅R̅ signal returns to the low state (to disable the sensing enable block 120). With such a configuration, each of the switchable coupling path associated with the first and second switches S2, S1 is non-conducting during the fuse sensing operation, and conducting when the sensing operation is completed. Such conducting coupling path allows each of the output nodes Out1, Out2 to go to the voltage Vdd, and help prevent any type of voltage disturbances to the output nodes Out1, Out2. Accordingly, the fuse state output from the SR latch circuit (e.g., FIG. 4) can be maintained in a more stable manner.

FIG. 20 shows another variation to the fuse sensing configuration of FIG. 3. In the example of FIG. 20, the decision block 140, the sensing current control block 130, and the sensing enable block 120 can be similar to the corresponding blocks in the configuration of FIG. 3.

In the example of FIG. 20, each of the nodes 141, 142 in the decision block 140 can be coupled to its respective output node (Out1 or Out2) by a switchable resistive path to provide a residual voltage discharge functionality. For example, the node 141 can be coupled to the first output node Out1 by a first path 190a having an output resistance Rout in series with a first switch S4 (e.g., a PFET), and node 142 can be coupled to the second output node Out2 by a second path 190b having an output resistance Rout in series with a second switch S3 (e.g., a PFET). Each of the first and second switches S4, S3 can be turned on by application of an enable signal, and be turned off by removal of such an enable signal.

In some embodiments, a POR signal can be utilized to enable or disable each of the first and second switches S4, S3. As described herein in reference to FIGS. 7-10, a POR signal remains low during the sensing operation, and goes high when the sensing operation is completed. Thus, based on such timing of the POR signal, for each of the first and second switches S4, S3, the enable signal can be high (to turn on the corresponding switch) during the sensing operation, and become low (to turn off the corresponding switch) when the sensing operation is complete.

In the foregoing configuration, the switchable resistive paths from the nodes 141, 142 to their respective output nodes Out1, Out2 can provide additional discharging paths to help maintain the nodes 141, 142 closer to ground. Such a configuration can be important for obtaining correct sensing values when the Vio signal ramps up initially.

It is noted that the addition of the output resistances Rout in the resistive paths 190a, 190b can allow the fuse sensing circuit to maintain correct functionality even with smaller dimensioned devices. As described in reference to FIGS. 14 and 15, the smallest width W (for a length L of 0.350 μm) of the example device for providing a correct fuse state output value is 0.9 μm. With the configuration of FIG. 20, however, correct fuse state output values can be obtained with the width W being as low as 0.5 μm.

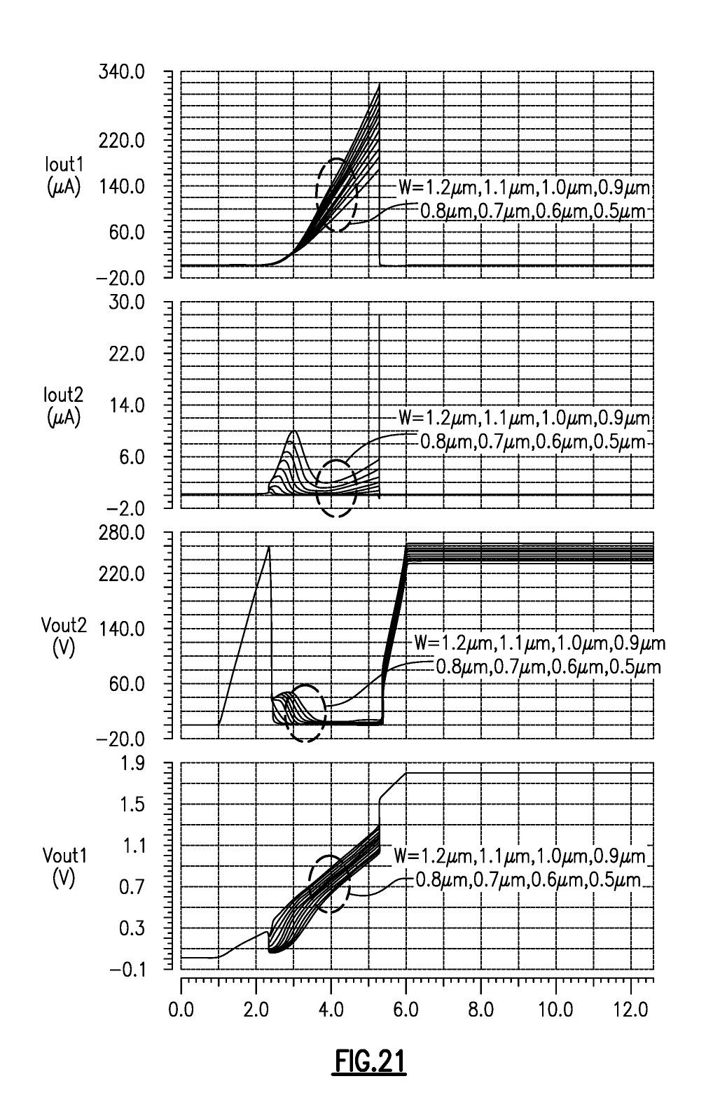

FIG. 21 shows examples of Iout1, Iout2, Vout2 and Vout1 for similar width values (for L=0.350 μm) as in the example of FIG. 15. As seen in FIG. 21, each of the current and voltage plots are grouped in a single cluster rather than two separate clusters (with one cluster corresponding to incorrect fuse state values due to the smaller widths).

It is noted that the addition of the resistive paths 190a, 190b in the example of FIGS. 20 and 21 can provide the foregoing advantageous feature (e.g., being able to make the device size smaller), but at the expense of making the fuse sensing circuit slightly larger. Thus, depending on a particular design, such resistive paths may or may not be utilized.

FIG. 22 shows that in some embodiments, a fuse system 100 having one or more features as described herein can be implemented in an electronic system 400 for initializing and/or resetting one or more integrated circuits. Such an electronic system can be configured to receive a signal such as a Vio signal by a control system 404 and a POR circuit 402. The POR circuit 402 can generate a POR signal and related signal(s) such as a P̅O̅R̅ signal, and provide such signals to the control system 404 as well as the fuse system 100. Based on such signals, the fuse system 100 can determine the states of various fuses associated with the one or more integrated circuits, and provide such fuse states to the control system 404. Based on such fuse states, the control system 404 can generate control signals 406 to initialize and/or reset the one or more integrated circuits.

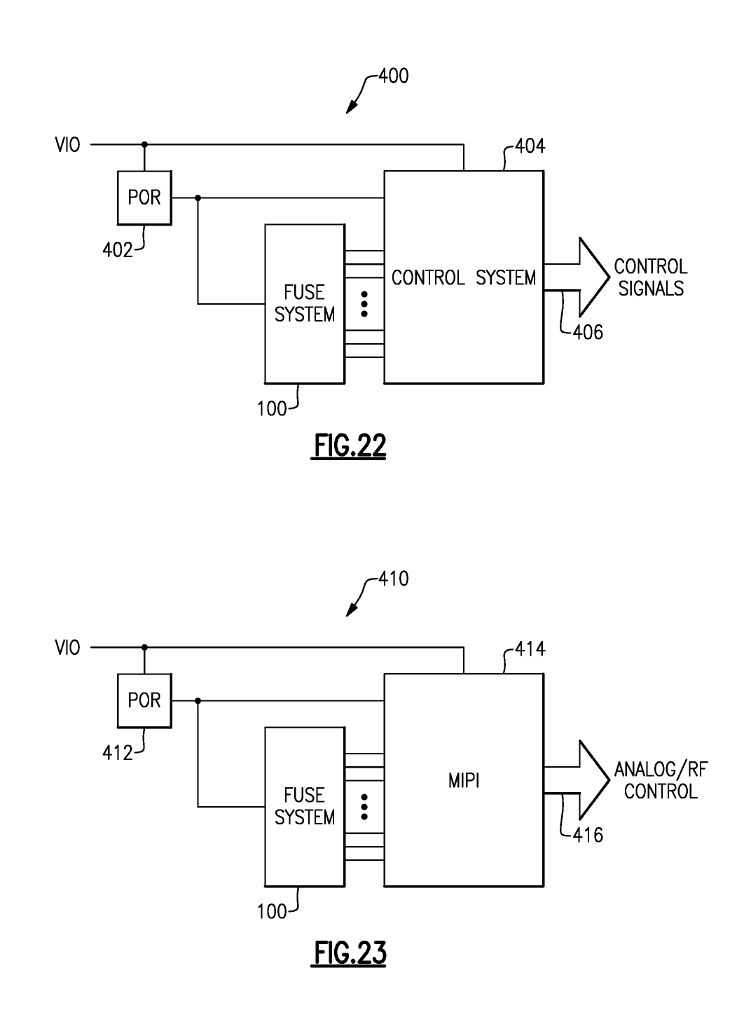

FIG. 23 shows that in some embodiments, the electronic system 400 of FIG. 22 can be, for example, a radio-frequency (RF) system 410. Such an RF system can include a fuse system 100 having one or more features as described herein. Such a fuse system can be utilized for initializing and/or resetting one or more integrated circuits, including one or more RF circuits. Such an RF system can be configured to receive a signal such as a Vio signal by a control system such as a MIPI (Mobile Industry Processor Interface) controller 414 and a POR circuit 412. The POR circuit 412 can generate a POR signal and related signal(s) such as a P̅O̅R̅ signal, and provide such signals to the MIPI controller 414 as well as the fuse system 100. Based on such signals, the fuse system 100 can determine the states of various fuses associated with the one or more RF circuits, and provide such fuse states to the MIPI controller 414. Based on such fuse states, the MIPI controller 414 can generate control signals 416 to initialize and/or reset the one or more RF circuits.

FIG. 24 shows that in some embodiments, a fuse system 100 having one or more features as described herein can be implemented in an electronic module 500. Such a module can include a packaging substrate 502 configured to receive a plurality of components, including one or more semiconductor die having integrated circuits. As described herein, such semiconductor die can include a number of fuses with different states. Thus, the fuse system 100 can sense such fuse states as described herein, and provide such information to a control system 404. The control system 404 can generate control signals based on such fuse states, and such control signals can be utilized to initialize and/or reset one or more integrated circuits 504 in the one or more semiconductor die.

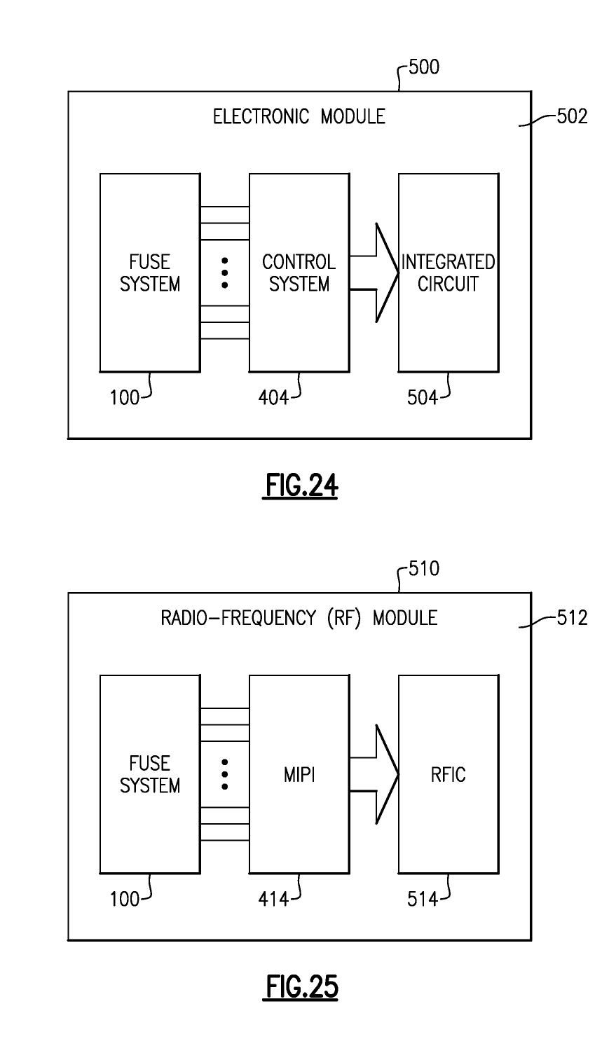

FIG. 25 shows that in some embodiments, a fuse system 100 having one or more features as described herein can be implemented in an RF module 510. Such a module can include a packaging substrate 512 configured to receive a plurality of components, including one or more semiconductor die having RF circuits. As described herein, such semiconductor die can include a number of fuses with different states. Thus, the fuse system 100 can sense such fuse states as described herein, and provide such information to a controller 414 such as a MIPI controller. The controller 414 can generate control signals based on such fuse states, and such control signals can be utilized to initialize and/or reset one or more RF circuits 514 in the one or more semiconductor die.

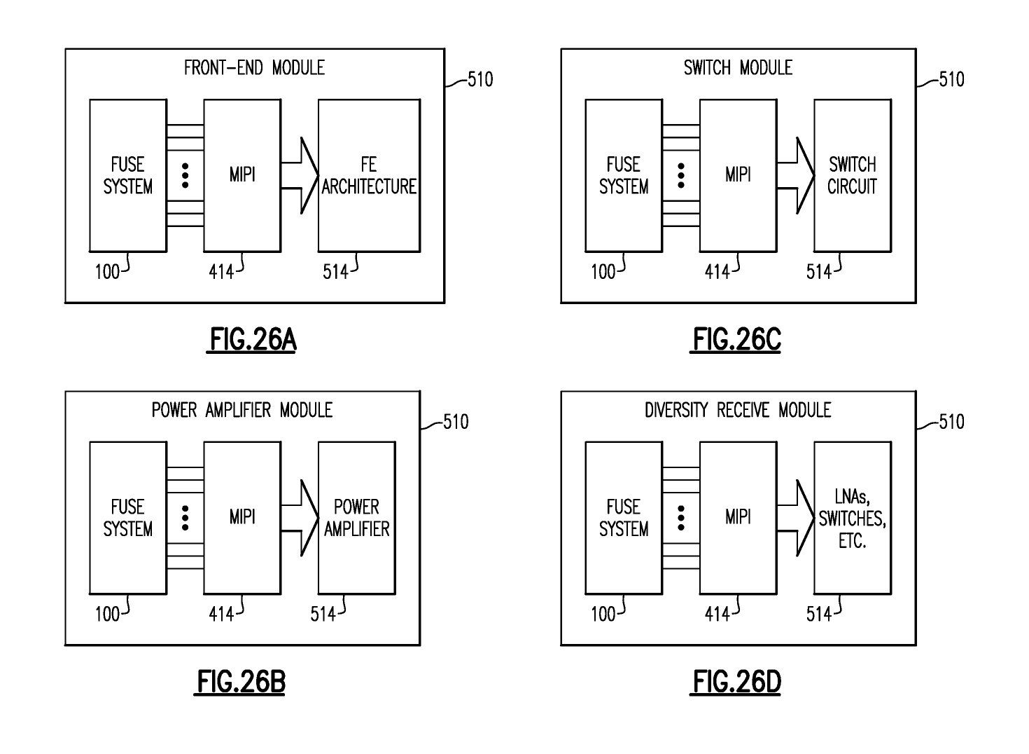

FIGS. 26A-26D show RF modules that can be more specific examples of the RF module of FIG. 25. FIG. 26A shows that in some embodiments, the RF module 510 of FIG. 25 can be implemented as a front-end module (FEM) 510. Such a module can include a one or more semiconductor die having RF circuits associated with a front-end (FE) architecture. As described herein, such semiconductor die can include a number of fuses with different states. Thus, the fuse system 100 can sense such fuse states as described herein, and provide such information to a controller 414 such as a MIPI controller. The controller 414 can generate control signals based on such fuse states, and such control signals can be utilized to initialize and/or reset one or more RF circuits 514 associated with the front-end architecture.

FIG. 26B shows that in some embodiments, the RF module 510 of FIG. 25 can be implemented as a power amplifier module (PAM) 510. Such a module can include a one or more semiconductor die having RF circuits associated with power amplifier(s) and related circuits. As described herein, such semiconductor die can include a number of fuses with different states. Thus, the fuse system 100 can sense such fuse states as described herein, and provide such information to a controller 414 such as a MIPI controller. The controller 414 can generate control signals based on such fuse states, and such control signals can be utilized to initialize and/or reset one or more RF circuits 514 associated with the power amplifier(s) and related circuits.

FIG. 26C shows that in some embodiments, the RF module 510 of FIG. 25 can be implemented as a switch module 510 (e.g., an antenna switch module (ASM)). Such a module can include a one or more semiconductor die having RF circuits associated with switches and related circuits. As described herein, such semiconductor die can include a number of fuses with different states. Thus, the fuse system 100 can sense such fuse states as described herein, and provide such information to a controller 414 such as a MIPI controller. The controller 414 can generate control signals based on such fuse states, and such control signals can be utilized to initialize and/or reset one or more RF circuits 514 associated with the switches and related circuits.

FIG. 26D shows that in some embodiments, the RF module 510 of FIG. 25 can be implemented as a diversity receive (DRx) module 510. Such a module can include a one or more semiconductor die having RF circuits associated with low-noise amplifiers (LNAs), switches, etc., and related circuits. As described herein, such semiconductor die can include a number of fuses with different states. Thus, the fuse system 100 can sense such fuse states as described herein, and provide such information to a controller 414 such as a MIPI controller. The controller 414 can generate control signals based on such fuse states, and such control signals can be utilized to initialize and/or reset one or more RF circuits 514 associated with the LNAs, switches, etc., and related circuits.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

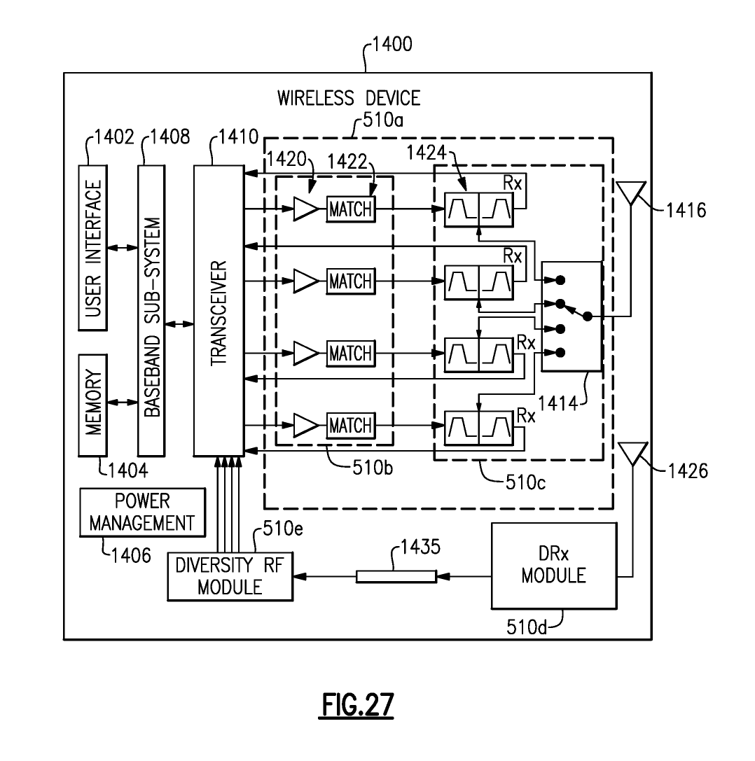

FIG. 27 depicts an example wireless device 1400 having one or more advantageous features described herein. In some embodiments, a fuse system having one or more features as described herein can be implemented in a number of places in such a wireless device. For example, in some embodiments, such advantageous features can be implemented in a module such as a front-end module 510a, a power amplifier module 510b, a switch module 510c, a diversity receive module 510d, and/or a diversity RF module 510e.

In the example of FIG. 27, power amplifiers (PAs) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 is also shown to be connected to a power management component 1406 that is configured to manage power for the operation of the wireless device 1400. Such power management can also control operations of the baseband sub-system 1408 and other components of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example of FIG. 27, the diversity receive module 510d can be implemented relatively close to one or more diversity antennas (e.g., diversity antenna 1426). Such a configuration can allow an RF signal received through the diversity antenna 1426 to be processed (in some embodiments, including amplification by an LNA) with little or no loss of and/or little or no addition of noise to the RF signal from the diversity antenna 1426. Such processed signal from the diversity receive module 510d can then be routed to the diversity RF module 510e through one or more signal paths (e.g., through a lossy line 1435).

In the example of FIG. 27, a main antenna 1416 can be configured to, for example, facilitate transmission of RF signals from the PAs 1420. Such amplified RF signals from the PAs 1420 can be routed to the antenna 1416 through respective matching networks 1422, duplexers 1424, and am antenna switch 1414. In some embodiments, receive operations can also be achieved through the main antenna. Signals associated with such receive operations can be routed to a receiver circuit through the antenna switch 1414 and the respective duplexers 1424.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A fuse state sensing circuit comprising:
an enable block configured to enable a flow of a fuse current resulting from a supply voltage to a fuse element upon receipt of an enable signal substantially at the same time as when the supply voltage is applied;
a current control block tailored to control an amount of the fuse current; and
a decision block implemented to generate an output representative of a state of the fuse element based on the fuse current, the output generated during a ramp-up portion of the application of the supply voltage.

2. The fuse state sensing circuit of claim 1 wherein the enable block is further configured to enable a flow of a reference current resulting from the supply voltage to a reference element upon receipt of the enable signal, the current control block further tailored to control an amount of the reference current, the decision block further implemented to generate the output based on the fuse current and the reference current.

3. The fuse state sensing circuit of claim 2 wherein the decision block includes a supply node for receiving the supply voltage, such that the decision block receives the supply voltage.

4. The fuse state sensing circuit of claim 2 wherein the enable block includes a fuse node for connecting to the fuse element, such that the current control block is implemented between the decision block and the enable block.

5. The fuse state sensing circuit of claim 2 wherein the decision block, the enable block, and the current control block are interconnected by a fuse current path between a supply node configured to receive the supply voltage and a fuse node configured to be connected to the fuse element.

6. The fuse state sensing circuit of claim 5 wherein the decision block, the enable block, and the current control block are further interconnected by a reference current path between the supply node and a reference node configured to be connected to a reference element.

7. The fuse state sensing circuit of claim 6 wherein the reference element includes a reference resistance.

8. The fuse state sensing circuit of claim 6 wherein one end of the fuse element is connected to the fuse node and the other end of the fuse element is connected to a ground, and one end of the reference element is connected to the reference node and the other end of the reference element is connected to the ground, such that the fuse current path and the reference current path are electrically parallel between the supply node and the ground.

9. The fuse state sensing circuit of claim 6 wherein the fuse current path includes a decision transistor, a current control transistor, and an enable transistor implemented in series between the supply node and the fuse node.

10. The fuse state sensing circuit of claim 9 wherein the decision transistor is connected to the supply node and the enable transistor is connected to the fuse node, such that the current control transistor is between the decision transistor and the enable transistor.

11. The fuse state sensing circuit of claim 9 wherein the reference current path includes a decision transistor, a current control transistor, and an enable transistor implemented in series between the supply node and the reference node.

12. The fuse state sensing circuit of claim 11 wherein the decision transistor is connected to the supply node and the enable transistor is connected to the reference node, such that the current control transistor is between the decision transistor and the enable transistor.

13. (canceled)

14. (canceled)

15. (canceled)

16. (canceled)

17. (canceled)

18. (canceled)

19. (canceled)

20. (canceled)

21. (canceled)

22. (canceled)

23. The fuse state sensing circuit of claim 11 wherein the decision transistor of the fuse current path and the decision transistor of the reference current path are parts of the decision block.

24. The fuse state sensing circuit of claim 23 wherein the decision block further includes a first output node along the reference current path, and a second output node along the fuse current path, the first and second output nodes configured to provide respective output voltages based on the state of the fuse element.

25. The fuse state sensing circuit of claim 24 wherein each of the decision transistor of the fuse current path and the decision transistor of the reference current path includes a gate, a source, and a drain, such that the source of each decision transistor is connected to the supply node and the drain of each decision transistor is connected to a respective one of the first and second output nodes.

26. (canceled)

27. The fuse state sensing circuit of claim 25 wherein the decision transistor of the reference current path and the decision transistor of the fuse current path are cross-coupled, such that the gate of one decision transistor is connected to the drain of the other decision transistor.

28. The fuse state sensing circuit of claim 27 wherein the output of the decision block includes a difference between the first output voltage and the second output voltage.

29. The fuse state sensing circuit of claim 28 wherein the decision block is configured such that the output has a positive value when the fuse element is in an intact state and a negative value when the fuse element is in a blown state.

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. A semiconductor die comprising:
a semiconductor substrate;
a fuse element implemented on the semiconductor substrate; and
a fuse sensing circuit implemented on the semiconductor substrate and in communication with the fuse element, the fuse sensing circuit including an enable block configured to enable a flow of a fuse current resulting from a supply voltage to the fuse element upon receipt of an enable signal substantially at the same time as when the supply voltage is applied, the fuse sensing circuit further including a current control block tailored to control an amount of the fuse current, and a decision block implemented to generate an output representative of a state of the fuse element based on the fuse current, the output generated during a ramp-up portion of the application of the supply voltage.

42. An electronic module comprising:
a packaging substrate configured to receive a plurality of components;
a semiconductor die mounted on the packaging substrate and including an integrated circuit and a fuse element;
a fuse sensing circuit in communication with the fuse element and including an enable block configured to enable a flow of a fuse current resulting from a supply voltage to the fuse element upon receipt of an enable signal substantially at the same time as when the supply voltage is applied, the fuse sensing circuit further including a current control block tailored to control an amount of the fuse current, and a decision block implemented to generate an output representative of a state of the fuse element based on the fuse current, the output generated during a ramp-up portion of the application of the supply voltage; and
a controller in communication with the fuse sensing circuit and configured to receive an input signal representative of the output of the fuse sensing circuit, the controller further configured to generate a control signal based on the input signal.

43-53. (canceled)
